(19) United States
(12) Patent Application Publication
(10) Pub. No.: US 2007/0238328 A1
(43) Pub. Date: Oct. 11, 2007

(54) Surface-mountable optoelectronic component

(75) Inventor: Christian Ferstl, Neutraubling (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 11/402,447

(22) Filed: Apr. 11, 2006

(30) Foreign Application Priority Data
Apr. 15, 2005 (DE) 10 2005 017 527.9

(51) Int. Cl. H05K 1/00

(52) U.S. Cl. 439/83

(57) ABSTRACT

In a surface-mountable optoelectronic component having a housing body (1), which has a housing base area (9) and at least a first housing side area (15) and a second housing side area (16), the first housing side area (15) and the second housing side area (16) lying opposite one another and the housing base area (9) extending from the first housing side area (15) in the direction toward the second housing side area (16), comprising a connection location (7), which is arranged at the housing base area (9) and is adjacent to the first housing side area (15), the connection location (7) being provided for connecting the component to a carrier body (2) by means of a solder (10), the housing body (1) has a cutout (11) adjoining the connection location (7) and extending from the housing base area (9) into the housing body (1), the formation of an outer solder fillet (17) at the first housing side area (15) and of an inner solder fillet (18) at a side area (13) of the cutout (11) that adjoins the connection location (7) being provided by the solder (10). The resulting torque exerted on the housing body (1 ) by the solder fillets (17, 18) is reduced in this way.

### RELATED APPLICATIONS

This patent application claims the priority of German patent application no. 10 2005 017 527.9 filed Apr. 15, 2005, the disclosure content of which is hereby incorporated by reference.

### FIELD OF THE INVENTION

The invention relates to a surface-mountable optoelectronic component.

### BACKGROUND OF THE INVENTION

Surface-mountable optoelectronic components are generally fixed on a circuit board, in particular a printed circuit board (PCB), by means of soldering connections.

A surface-mountable semiconductor component fixed on a PCB by means of a soldering connection is known from U.S. Pat. No. 5,936,846, by way of example. FIG. 4 of this document, in particular, illustrates a surface-mountable component (SMD, surface mounted device) fixed on a PCB by means of a soldering location in the region of the side area of the housing. In this case, the solder forms an outer solder fillet between the PCB and the housing side area and an inner solder fillet between the PCB and the housing bottom area. Since the solder, in the event of melting, is displaced under the housing bottom area in part by the force due to the weight of the housing, but on the other hand is not displaced at the side area of the housing, the outer solder fillet and the inner solder fillet are formed asymmetrically.

Through the solder fillets, on account of the surface tension of the solder, a force is in each case exerted on the housing of the component, the forces in each case having a tangential component, that is to say a component acting parallel to the surface of the housing bottom or of the carrier substrate, which component is directed toward the solder fillet. On account of the form of the outer and inner solder fillets not being symmetrical with respect to one another, the tangentially acting forces generally do not compensate for one another. In particular, the tangential force exerted on the housing by the outer solder fillet is generally greater than the oppositely acting tangential force of the inner solder fillet.

The resulting tangential force acting on the housing can lead to cracking in the solder location. Furthermore, there is the risk of the tangentially acting force exerting a torque on the housing body, which, in particular during the soldering operation when the solder is still molten, can result in the housing tilting relative to the carrier surface. This so-called tombstoning effect may occur particularly in the case of optoelectronic components which have a comparatively light plastic housing without a leadframe. The basic construction of such a component without a leadframe is known from published US Patent Application No. 2004/0232435 A1 by way of example.

### SUMMARY OF THE INVENTION

One object of the present invention is to provide an improved surface- mountable optoelectronic component which is used for soldering mounting onto a carrier body, in the case of which in particular a resulting torque exerted on the housing body by the solder fillets is reduced.

This and other objects are attained in accordance with one aspect of the present invention directed to a surface-mountable optoelectronic component that has a housing body with a housing base area and at least a first housing side area and a second housing side area, the first housing side area and the second housing side area lying opposite one another and the housing base area extending from the first housing side area in the direction toward the second housing side area. Furthermore, a connection location is arranged at the housing base area and is adjacent to the first housing side area, the connection location being provided for connecting the component to a carrier body by means of a solder. The housing body has a cutout adjoining the connection location and extending from the housing base area into the housing body, the formation of an outer solder fillet at the first housing side area and of an inner solder fillet at a side area of the cutout that adjoins the connection location being provided by the solder.

The solder, in the event of melting during the soldering operation, can advantageously penetrate into a partial region of the cutout adjoining the connection location in order to form, in particular at a side area of the cutout that faces the connection location, an inner solder fillet which is comparatively large in comparison with an inner solder fillet that would form below the housing base area in the case of a conventional housing. The inner solder fillet and the outer solder fillet advantageously have an essentially identical height relative to the carrier surface and/or an essentially identical curvature. The inner solder fillet and the outer solder fillet are particularly preferably symmetrical with respect to one another.

In this way, a torque exerted on the housing body by the outer solder fillet is advantageously reduced or even compensated for by an opposite torque exerted on the housing body by the inner solder fillet. The torque is preferably reduced at least in such a way that the housing body is not tilted by a torque acting on it during the soldering operation when the solder is still molten. Furthermore, cracking in the solder location is also prevented in this way.

In one advantageous refinement of the invention, a cross section of the cutout tapers proceeding from the housing base area toward the interior of the housing body. The cutout preferably has a V-shaped or trapezoidal cross section.

Preferably, the cutout has a metalized side area adjoining the connection location and a nonmetalized side area. What is advantageously achieved in this way is that the inner solder fillet forms at the metalized side area of the cutout and, in particular, not at the nonmetalized side area of the cutout. The inner solder fillet thus serves to improve electrical contact.

The optoelectronic component is preferably based on molded interconnected device (MID) technology. The housing body advantageously contains at least two different plastics, one of the plastics not being metalizable and one of the plastics being metalizable, and the housing body has a metalization at the surface of the metalizable plastic.

The housing body may be produced, in particular, by a two-component injection-molding method, the two components being formed by a metalizable plastic and a nonmetalizable plastic.

The metalization is preferably divided into at least two metalization regions, which are electrically isolated from one another, by an insulating spacer formed from the nonmetalizable plastic.

The cutout is advantageously formed at an interface between a metalized region of the metalizable plastic and a region of the nonmetalizable plastic in such a way that it has a metalized side area facing the adjoining connection location and an opposite, nonmetalized side area.

The invention is particularly advantageous for housing bodies which, in contrast to conventional housing forms in which a metallic leadframe is generally encapsulated by a plastic by injection molding, have no leadframe. Since such a housing that does not comprise a leadframe has a comparatively low weight, the risk of the housing body tilting during soldering mounting due to a torque acting on the housing body is comparatively high in the case of such a housing.

In one preferred embodiment, the optoelectronic component comprises at least one radiation-receiving or radiation-emitting semiconductor chip, for example a light-emitting diode chip or a laser diode chip.

The semiconductor chip is preferably arranged in a further cutout of the housing body, which further cutout is not formed at the housing base area. The further cutout is advantageously provided with a metalization that serves as a reflector for the radiation emitted by the radiation-emitting semiconductor chip.

The further cutout, in which the semiconductor chip is arranged, may be formed e.g. at an area of the housing body that lies opposite to the housing base area.

As an alternative, the further cutout, in which the semiconductor chip is arranged, may also be formed at an area of the housing body that is arranged vertically with respect to the housing base area. In particular, the optoelectronic component may contain a light-emitting diode chip or laser diode chip having a main radiation direction parallel to the housing base area.

In a further embodiment of the invention, a second connection location is arranged at the housing base area and is adjacent to the second housing side area, the second connection location being provided for connecting the component to a carrier body by means of a solder and the housing body has a second cutout adjoining the second connection location and extending from the housing base area into the housing body, the formation of an outer solder fillet at the second housing side area and of an inner solder fillet at a side area of the second cutout that adjoins the second connection location being provided by the solder. The above-described advantages and preferred refinements of the first cutout correspondingly hold true for the second cutout at the housing base area.

In this embodiment, a radiation-emitting and/or radiation-receiving semiconductor chip is preferably electrically conductively connected by a first electrical contact to the first connection location and by a second electrical contact to the second connection location. The electrically conductive connection between the semiconductor chip and the first connection location and the second connection location is preferably effected in each case by means of the above-described metalization regions that are electrically insulated from one another, a first metalization region comprising the first connection location and a second metalization region comprising the second connection location. By way of example, a first electrical contact of the semiconductor chip is electrically conductively connected to a first metalization region and a second electrical contact of the semiconductor chip is electrically conductively connected to the second metalization region. In this way, the semiconductor chip is electrically conductively connected to the first connection location via the first metalization region and to the second connection location via the second metallization region.

Furthermore, at least one of the metallization regions may advantageously simultaneously have an optical function; in particular, a metalized region of the housing body may serve as a reflector for electromagnetic radiation emitted by a radiation- emitting semiconductor chip arranged at the housing body.

### BRIEF DESCRIPTION OF THE DRAWING

The Figure shows a schematic illustration of a cross section through a surface-mountable optoelectronic component with a carrier body in accordance with an exemplary embodiment of the invention.

### DETAILED DESCRIPTION OF THE DRAWING

The surface-mountable optoelectronic component in accordance with an exemplary embodiment of the invention as illustrated in the figure comprises a housing body 1, which has a first connection location 7 and a second connection location 8 at a housing base area 9 facing a carrier 2. At the first connection location 7 and the second connection location 8, the housing body 1 is in each case connected to a carrier body 2 by a solder 10. The carrier body 2 is for example a circuit board, in particular a printed circuit board (PCB). In particular, the carrier body 2 may be provided with conductor tracks 3, 4 to which the optoelectronic component is electrically conductively connected at the connection locations 7, 8 by means of the solder 10.

At the housing base area 9, two cutouts 11, 12 are formed in the housing body 1. The first cutout 11 adjoins the first connection location 7 and the second cutout 12 adjoins the second connection location 8. The first connection location 7 adjoins a first housing side area 15 of the housing body 1 at a side remote from the first cutout 11, and the second connection location 8 adjoins a second housing side area 16 of the housing body 1 at a side remote from the second cutout 12.

At the connection locations 7, 8, the solder 10 in each case forms an outer solder fillet 17, which runs from the carrier body 2 to the housing side area 15, 16 adjoining the connection location 7, 8, and an inner solder fillet 18, which in each case runs from the carrier body 2 to a side area 13, 14 of the cutout 11, 12 that adjoins the connection location 7, 8.

The outer solder fillets 17 in each case exert a torque M₁ on the housing body 1. The inner solder fillets 18 in each case exert a torque M₂, directed oppositely to the torque M₁, on the housing body 1. In this way, the torque M₁ exerted by the outer solder fillets 18 is advantageously reduced or particularly preferably even compensated for by the oppositely directed torque M₂. Consequently, this reduces the risk of the housing body 1 being tilted by a torque M₁ exerted by the outer solder fillet 17 during the soldering operation, when the solder 10 has not yet solidified, in such a way that, by way of example, the housing base area 9 does not run parallel to the surface of the carrier body 2. Furthermore, cracking in the solder 10 is prevented by the reduction of the resulting torque.

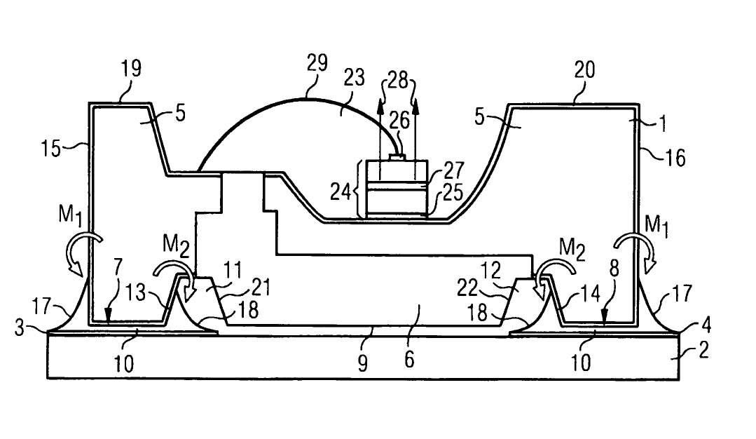

Preferably, a cross section of the cutouts 11, 12 tapers proceeding from a plane formed by the housing base area 9 toward the interior of the housing body 1. By way of example, the cutouts 11, 12, as illustrated in FIG. 1, may have a trapezoidal cross section. As an alternative, the cutouts may also have a different cross-sectional area, for example a V-shaped or semicircular cross section.

The housing body 1 advantageously contains at least two housing parts 5, 6 connected to one another. In particular, the housing body 1 may contain a first housing part 5, which is formed from a metalizable plastic, and a second housing part 6, which is formed from a nonmetalizable plastic. A housing body 1 of this type is produced e.g. in a two-component injection molding method, the metalizable plastic of the first housing part 5 being the first component and the nonmetalizable plastic of the second housing part 6 being the second component.

At least one part of the surface of the housing part 5, which comprises the metalizable plastic, is provided with a metalization 19, 20. By contrast, the housing part 6 made of the nonmetalizable plastic is not metalized at its surface and advantageously constitutes an insulating spacer that subdivides the metalization 19, 20 applied to the housing part 5 into two regions that are electrically insulated from one another, a first metalization region 19 comprising the first connection location 7 and a second metalization region 20 comprising the second connection location 8.

The cutouts 11, 12 are preferably in each case arranged at an interface between the housing part 5 made of the metalizable plastic and the housing part 6 made of the nonmetalizable plastic in such a way that they each have a side area 13, 14 that faces the adjoining connection location 7, 8 and is formed by a surface of the metalizable plastic part 5, and an opposite side area 21, 22 formed by a surface of the nonmetalized plastic part 6. The side areas 13, 14 of the cutout that adjoin the connection locations 7, 8 are preferably provided in each case with a partial region of the metalization regions 19, 20. This has the advantage that the inner solder fillets 18 form in each case at the metalized side areas 13, 14 and not at the opposite side areas 21, 22 of the cutouts.

The optoelectronic component preferably comprises at least one radiation- emitting and/or radiation-receiving semiconductor chip, which is arranged e.g. in a cutout 23 of the housing body 1 lying opposite to the housing base area 9. By way of example, the semiconductor chip is a radiation-emitting semiconductor chip 24 comprising an active zone 27, from which electromagnetic radiation 28, for example ultraviolet, visible or infrared light, is emitted.

The semiconductor chip 24 preferably contains a III-V compound semiconductor material, in particular InₓAl_{y}Ga_{I-x-y}N, InₓAl_{y}Ga_{I-x-y}P or InₓAl_{y}Ga_{I-x-y}As, in each case where 0≦x≦I, 0≦y≦I and x+y≦I. In this case, the III-V compound semiconductor material need not necessarily have a mathematically exact composition according to one of the above formulae. Rather, it may have one or more dopants and also additional constituents which essentially do not change the physical properties of the material. For the sake of simplicity, however, the above formulae comprise only the essential constituents of the crystal lattice even though these may be replaced in part by small quantities of further substances.

The radiation-emitting semiconductor chip 24 advantageously has a first contact, for example a bonding pad 26, via which the semiconductor chip 24 is electrically conductively connected to the first metalization region 19 for example by means of a bonding wire 29. Furthermore, the radiation-emitting semiconductor chip 24 has a second contact, for example a contact metalization 25, by which the semiconductor chip 24 is electrically conductively connected to the second metalization region 20. In this way, the first contact 26 of the semiconductor chip is electrically conductively connected via the bonding wire 29 and the first metalization region 19 to the first connection location 7 and the second contact 25 is electrically conductively connected via the second metalization region 20 to the second connection location 8. In contrast to optoelectronic components which have a leadframe, the electrical contact- connection of the semiconductor chip is thus advantageously effected via metalized regions of the surface of the housing body 1.

The surfaces of the metalization regions 19, 20 that face the cutout 23 advantageously constitute a reflection-increasing layer for the radiation 28 emitted by the radiation-emitting semiconductor chip 24. The metalization regions 19, 20 thus advantageously have, on the one hand, the electrical function for electrically conductively connecting the semiconductor chip 24 to the connection locations 7, 8 and, on the other hand, the optical function for reflecting radiation that is emitted in the direction of the housing body 1 in order, in particular, to increase the radiation intensity of a main radiation direction or to protect the housing parts 5, 6 made of plastic against UV radiation.

The invention is not restricted by the description on the basis of the exemplary embodiments. Rather, the invention encompasses any new feature and also any combination of features, which is particular comprises any combination of features in the patent claims, even if this feature or this combination itself is not explicitly specified in the patent claims or exemplary embodiments.

I claim:

1. A surface-mountable optoelectronic component having a housing body, which has a housing base area and at least a first housing side area and a second housing side area, the first housing side area and the second housing side area lying opposite one another and the housing base area extending from the first housing side area in the direction toward the second housing side area, comprising a connection location, which is arranged at the housing base area and is adjacent to the first housing side area, the connection location being provided for connecting the component to a carrier body by means of a solder,
wherein
the housing body has a cutout adjoining the connection location and extending from the housing base area into the housing body, the formation of an outer solder fillet at the first housing side area and of an inner solder fillet at a side area of the cutout that adjoins the connection location being provided by the solder.

2. The surface-mountable optoelectronic component as claimed in claim 1,
wherein
a torque (M₁) exerted on the housing body by the outer solder fillet is reduced by an opposite torque (M₂) exerted on the housing body by the inner solder fillet.

3. The surface-mountable optoelectronic component as claimed in claim 1,
wherein
a cross section of the cutout tapers proceeding from the housing base area toward the interior of the housing body.

4. The surface-mountable optoelectronic component as claimed in claim 3,
wherein
the cutout has a V-shaped or trapezoidal cross section.

5. The surface-mountable optoelectronic component as claimed in claim 1,
wherein
the cutout has a metalized side area adjoining the connection location and a nonmetalized side area, the inner solder fillet being formed at the metalized side area.

6. The surface-mountable optoelectronic component as claimed in claim 1,
wherein
the housing body contains at least two different plastics one of the plastics not being metalizable and one of the plastics being metalizable, and the housing body has a metalization at the surface of the metalizable plastic.

7. The surface-mountable optoelectronic component as claimed in claim 6,
wherein
the metalization is divided into at least two metalization regions, which are electrically isolated from one another, by an insulating spacer formed from the nonmetalizable plastic.

8. The surface-mountable optoelectronic component as claimed in claim 5,
wherein
the housing body contains at least two different plastics one of the plastics not being metalizable and one of the plastics being metalizable, and the housing body has a metalization at the surface of the metalizable plastic;
the metalization is divided into at least two metalization regions, which are electrically isolated from one another, by an insulating spacer formed from the nonmetalizable plastic; and
one of the metalization regions contains the metalized side area of the cutout, and the nonmetalized side area of the cutout is a part of the surface of the nonmetalizable plastic.

9. The surface-mountable optoelectronic component as claimed in claim 6,
wherein
the housing body is produced by a two-component injection-molding method, the two components being the two different plastics.

10. The surface-mountable optoelectronic component as claimed in claim 1,
wherein
the component has no leadframe.

11. The surface-mountable optoelectronic component as claimed in claim 1,
wherein
it comprises at least one radiation-emitting or radiation-receiving semiconductor chip.

12. The surface-mountable optoelectronic component as claimed in claim 11,
wherein
the semiconductor chip is arranged in a further cutout of the housing body, which further cutout is not formed at the housing base area.

13. The surface-mountable optoelectronic component as claimed in claim 12,
wherein
the further cutout is formed at an area of the housing body that lies opposite to the housing base area.

14. The surface-mountable optoelectronic component as claimed in claim 12,
wherein
the further cutout is formed at a surface of the housing body that is arranged vertically with respect to the housing base area.

15. The surface-mountable optoelectronic component as claimed in claim 1,
wherein
a second connection location is arranged at the housing base area and is adjacent to the second housing side area, the second connection location being provided for connecting the component to the carrier body by means of the solder, and the housing body has a second cutout adjoining the second connection location and extending from the housing base area into the housing body, and the formation of an outer solder fillet at the second housing side area and of an inner solder fillet at a side area of the second cutout that adjoins the second connection location is provided by the solder.
